(19) United States
(12) Patent Application Publication
(10) Pub. No.: US 2013/0106450 A1
(43) Pub. Date: May 2, 2013

(54) DRIVE CIRCUIT AND TEST APPARATUS

(71) Applicants: Masashi WATANABE, Saitama (JP); Kensuke SOEDA, (US); Naoki MATSUMOTO, Saitama (JP)

(72) Inventors: Masashi WATANABE, Saitama (JP); Kensuke SOEDA, (US); Naoki MATSUMOTO, Saitama (JP)

(73) Assignee: ADVANTEST CORPORATION, Tokyo (JP)

(21) Appl. No.: 13/562,314

(22) Filed: Jul. 31, 2012

(30) Foreign Application Priority Data
Oct. 28, 2011 (JP) 2011-236735

(51) Int. Cl. G05F 5/00; G01R 31/28

(52) U.S. Cl. 324/750.01; 323/299

(57) ABSTRACT

The response characteristics of an output signal and current consumption are kept constant. A drive circuit for outputting an output signal having a voltage determined by a logic of an input signal includes a constant voltage generating section generating a constant bias voltage, a CML circuit outputting the output signal having the voltage determined by the logic of the input signal, where an amplitude of the output signal is determined by a constant current flowing through the CML circuit and a potential of the output signal is determined by the bias voltage, an adjustment constant current source that allows a constant current to flow out from a bias voltage output end of the constant voltage generating section, and a current setting section that sets in advance the constant current flowing into the adjustment constant current source, according to the constant current flowing through the CML circuit.

### BACKGROUND

1. Technical Field

The present invention relates to a drive circuit and a test apparatus.

2. Related Art

A known test apparatus has a current mode logic (CML) circuit as its drive circuit. The CML circuit includes a pair of transistors that are switched on/off according to a differential mode signal, a pair of output resistances that pull up the collectors of the respective transistors to a class-A power amplifier, and a constant current source that is commonly connected to the emitters of the respective transistors.

Patent Document 1: Japanese Patent Application Publication No. 2011-55484

The CML circuit outputs an output signal from the collector of one of the transistors. In the CML circuit, the value of the current provided by the constant current source is varied in order to vary the voltage amplitude of the output signal.

When the value of the current provided by the constant current source is varied in the CML circuit, however, this variation changes the output current of the class-A power amplifier and also the characteristics of the class-A power amplifier. In particular, if the idling current of the transistor of the output stage decreases, the output resistance of the class-A power amplifier increases and its response characteristics accordingly degrade.

In addition, if the value of the current provided by the constant current source is varied, the consumed current of the CML circuit also varies. When the CML circuit is applied as the drive circuit of a test apparatus, however, the response characteristics and the overall consumed current of the drive circuit preferably stay the same irrespective of the variation in the voltage amplitude of the test signal.

### SUMMARY

Therefore, it is an object of an aspect of the innovations herein to provide a drive circuit and a test apparatus, which are capable of overcoming the above drawbacks accompanying the related art. The above and other objects can be achieved by combinations described in the claims. A first aspect of the innovations may include a drive circuit for outputting an output signal having a voltage determined according to a logic of an input signal. The drive circuit includes a constant voltage generating section that generates a constant bias voltage, a current mode logic circuit that outputs the output signal having the voltage determined according to the logic of the input signal, where an amplitude of the output signal is determined by a value of a constant current flowing through the current mode logic circuit and a potential of the output signal is determined by a value of the bias voltage, an adjustment constant current source that allows a constant current of a set value to flow out from a bias voltage output end of the constant voltage generating section that is designed to output the bias voltage, and a current setting section that sets in advance the value of the constant current flowing into the adjustment constant current source, according to the value of the constant current flowing through the current mode logic circuit.

The summary clause does not necessarily describe all necessary features of the embodiments of the present invention. The present invention may also be a sub-combination of the features described above. The above and other features and advantages of the present invention will become more apparent from the following description of the embodiments taken in conjunction with the accompanying drawings.

### BRIEF DESCRIPTION OF THE DRAWINGS

FIG. 1 illustrates the configuration of a drive circuit 10 relating to an embodiment of the present invention.

FIG. 2 illustrates an exemplary waveform of an output signal output from the drive circuit 10.

FIG. 3 illustrates the configuration of a test apparatus 100 relating to an embodiment of the present invention, together with a device under test 200.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

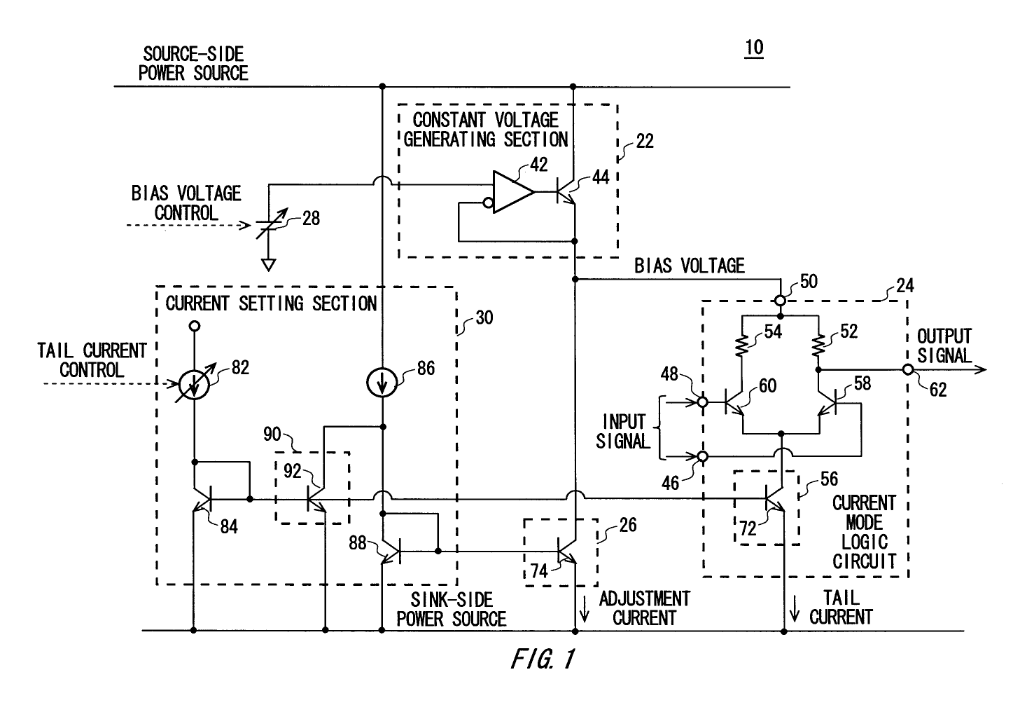

FIG. 1 illustrates the configuration of a drive circuit 10 relating to an embodiment of the present invention. The drive circuit 10 outputs an output signal having a voltage determined according to the logic of the input signal. According to the present embodiment, the drive circuit 10 receives, as the input signal, a differential mode signal representing a binary logic level. The drive circuit 10 outputs, as the output signal, a single-mode signal according to the logic of the input signal.

The drive circuit 10 includes a constant voltage generating section 22, a current mode logic circuit 24, an adjustment constant current source 26, a voltage setting outputting section 28, and a current setting section 30.

The constant voltage generating section 22 generates a constant bias voltage according to the voltage setting output from the voltage setting outputting section 28. According to the present embodiment, the constant voltage generating section 22 is a class-A power amplifier that amplifies the voltage setting output from the voltage setting outputting section 28 to generate a bias voltage and outputs the bias voltage.

The constant voltage generating section 22 includes, for example, an operational amplifier 42 and an npn transistor 44. The operational amplifier 42 receives the voltage setting from its non-inverted input end. The operational amplifier 42 feeds back the bias voltage output from the constant voltage generating section 22 and receives the bias voltage through its inverted input end.

The npn transistor 44 is connected at its collector to a source-side power source, connected at its emitter to the bias voltage output end of the constant voltage generating section 22 from which the bias voltage is output, and connected at its base to the output end of the operational amplifier 42. With such a configuration, the constant voltage generating section 22 is operable to adjust the bias voltage to become equal to the voltage setting even when the load connected to the output end of the bias voltage varies.

The current mode logic circuit 24 outputs an output signal having a voltage determined according to the logic of an input signal. The current mode logic circuit 24 has a constant current (tail current) flowing therethrough and the value of the constant current (tail current) flowing though the current mode logic circuit 24 determines the amplitude of the output signal. Furthermore, the value of the bias voltage determines the potential of the output signal output from the current mode logic circuit 24. More specifically, the value of the bias voltage determines one of a first-logic voltage of the output signal output from the current mode logic circuit 24 (for example, an L-logic voltage) and a second-logic voltage (for example, an H-logic voltage) of the output signal output from the current mode logic circuit 24.

According to the present embodiment, the current mode logic circuit 24 includes a positive input end 46, a negative input end 48, a bias input end 50, a positive output resistance 52, a negative output resistance 54, an in-logic constant current source 56, a positive switch 58, a negative switch 60, and a signal output end 62.

The positive input end 46 receives the positive signal of the input signal. The negative input end 48 receives the negative signal of the input signal. The bias input end 50 receives the bias voltage generated by the constant voltage generating section 22.

The positive output resistance 52 is connected at its one end to the bias input end 50 and connected at its other end to one end of the positive switch 58. The negative output resistance 54 is connected at its one end to the bias input end 50 and connected at its other end to one end of the negative switch 60. Here, the positive output resistance 52 and the negative output resistance 54 have, for example, substantially the same resistance value (for example, 75 ω or 50 ω).

The in-logic constant current source 56 provides a constant current (tail current) having a set value. More specifically, the in-logic constant current source 56 allows the tail current to flow from the positive switch 58 and the negative switch 60 to a sink-side power source. According to the present embodiment, the in-logic constant current source 56 is an npn transistor (a first mirror-side npn transistor 72). The first mirror-side npn transistor 72 is connected at its collector to the positive switch 58 and the negative switch 60 and connected at its emitter to the sink-side power source.

The positive switch 58 connects or disconnects between the in-logic constant current source 56 and the end of the positive output resistance 52 that is not connected to the bias input end 50, according to the logic of the positive signal of the input signal. For example, the positive switch 58 provides the on-state (connects) when the positive signal of the input signal has an H logic and provides the off-state (disconnects) when the positive signal of the input signal has an L logic.

According to the present embodiment, the positive switch 58 is an npn transistor. In this case, the positive switch 58 is connected at its collector to the end of the positive output resistance 52 that is not connected to the bias input end 50, connected at its emitter to the in-logic constant current source 56 (the collector of the first mirror-side npn transistor 72) and receives at its base the positive signal of the input signal.

The negative switch 60 connects or disconnects between the in-logic constant current source 56 and the end of the negative output resistance 54 that is not connected to the bias input end 50, according to the logic of the negative signal of the input signal. For example, the negative switch 60 provides the on-state (connects) when the negative signal of the input signal has an H logic and provides the off-state (disconnects) when the negative signal of the input signal has an L logic.

According to the present embodiment, the negative switch 60 is an npn transistor. In this case, the negative switch 60 is connected at its collector to the end of the negative output resistance 54 that is not connected to the bias input end 50, connected at its emitter to the in-logic constant current source 56 (the collector of the first mirror-side npn transistor 72) and receives at its base the negative signal of the input signal.

The signal output end 62 outputs, as the output signal, a single mode signal having a voltage determined according to the input signal. According to the present embodiment, the signal output end 62 is connected to the end of the positive output resistance 52 that is not connected to the bias input end 50. Alternatively, the signal output end 62 may be connected to the end of the negative output resistance 54 that is not connected to the bias input end 50.

With such a configuration, the current mode logic circuit 24 is switched on/off by a differential mode signal. In particular, the positive switch 58 and the negative switch 60 are switched on/off in a complementary manner. Specifically speaking, while one of the positive switch 58 and the negative switch 60 is switched on (connected), the other is switched off (disconnected). Accordingly, the constant current (tail current) provided by the in-logic constant current source 56 entirely flows into only one of the positive output resistance 52 and the negative output resistance 54 in the current mode logic circuit 24.

Accordingly, when the signal output end 62 is connected to the positive output resistance 52, the current mode logic circuit 24 outputs an L-logic voltage in response to the positive switch 58 being switched on (connected) and outputs an H-logic voltage in response to the positive switch 58 being switched off (disconnected). Furthermore, when the signal output end 62 is connected to the negative output resistance 54, the current mode logic circuit 24 outputs the L-logic voltage in response to the negative switch 60 being switched on (connected) and outputs the H-logic voltage in response to the negative switch 60 being switched off (disconnected).

Here, the H-logic voltage is equal to the bias voltage generated by the constant voltage generating section 22. The L-logic voltage is equal to a result of subtracting, from the bias voltage, the product of the constant current (tail current) provided by the in-logic constant current source 56 and the resistance value of the positive output resistance 52 or the negative output resistance 54. In other words, when Vh denotes the bias voltage, Iset denotes the tail current, and R denotes the resistance value of the positive output resistance 52 or the negative output resistance 54, the H-logic voltage can be represented as Vh and the L-logic voltage can be represented as Vh−(Iset×R).

The adjustment constant current source 26 allows a constant current (adjustment current) having a value set by the current setting section 30 to flow out from the bias voltage output end of the constant voltage generating section 22. According to the present embodiment, the adjustment constant current source 26 is provided between the bias voltage output end of the constant voltage generating section 22 and the sink-side power source. In the present embodiment, the adjustment constant current source 26 is an npn transistor (a second mirror-side npn transistor 74). The second mirror-side npn transistor 74 is connected at its collector to the bias voltage output end of the constant voltage generating section 22 and connected at its emitter to the sink-side power source.

The voltage setting outputting section 28 outputs voltage setting, which is used as a reference for the bias voltage to be applied to the current mode logic circuit 24. The voltage setting outputting section 28 increases or decreases the voltage setting according to control from outside. The voltage setting outputting section 28 may be a DA converter or a voltage source whose output voltage may vary according to control from outside. In this way, the voltage setting outputting section 28 can vary the potential of the output signal (the potential of the H-logic voltage or L-logic voltage) according to control from outside.

The current setting section 30 sets in advance the value of the constant current (tail current) flowing through the current mode logic circuit 24, according to control from outside. In this way, the current setting section 30 can vary the voltage amplitude of the output signal, according to control from outside.

The current setting section 30 also sets in advance the value of the constant current (adjustment current) flowing into the adjustment constant current source 26, according to the value of the constant current (tail current) flowing through the current mode logic circuit 24. Here, the expression “to set in advance” means that the current value may be set prior to the switching operation of the current mode logic circuit 24, not during the switching operation.

The current setting section 30 sets in advance the value of the constant current flowing into the adjustment constant current source 26, in such a manner that the total of the value of the constant current (tail current) flowing through the current mode logic circuit 24 and the value of the constant current (adjustment current) flowing into the adjustment constant current source 26 remains constant. With such a configuration, the current setting section 30 can control the current output from the constant voltage generating section 22 to remain constant irrespective of the voltage amplitude of the output signal and the potential of the output signal (the H-logic voltage or L-logic voltage).

In the present embodiment, the current setting section 30 includes a first constant current source 82, a first current-side npn transistor 84, a second constant current source 86, a second current-side npn transistor 88, and a dividing section 90. The first constant current source 82 provides a constant current having a value set from outside.

The first current-side npn transistor 84 is connected at its collector to the first constant current source 82 and connected at its emitter to the sink-side power source, and the base of the first current-side npn transistor 84 is shorted to the collector. With such a configuration, the first current-side npn transistor 84 operates as a diode so as to be capable of causing the constant current output from the first constant current source 82 to flow from the collector to the emitter.

Furthermore, the base of the first current-side npn transistor 84 is connected to the base of the first mirror-side npn transistor 72 constituting the in-logic constant current source 56 in the current mode logic circuit 24. Stated differently, the first current-side npn transistor 84 and the first mirror-side npn transistor 72 together serve as a current mirror circuit. Accordingly, the first mirror-side npn transistor 72 provides a current equal to a predetermined multiple (for example, ten-fold) of the current flowing through the first current-side npn transistor 84. In this manner, the current setting section 30 allows the current proportional to the current flowing through the first constant current source 82 to flow through the in-logic constant current source 56.

The second constant current source 86 provides a constant current determined according to the reference value for the current that is expected to flow thorough the adjustment constant current source 26. The second current-side npn transistor 88 is connected at its collector to the second constant current source 86 and connected at its emitter to the sink-side power source, and the base of the second current-side npn transistor 88 is shorted to the collector. With such a configuration, the second current-side npn transistor 88 serves as a diode and allows the constant current output from the second constant current source 86 to flow from the collector to the emitter.

The base of the second current-side npn transistor 88 is connected to the base of the second mirror-side npn transistor 74 constituting the adjustment constant current source 26. Stated differently, the second current-side npn transistor 88 and the second mirror-side npn transistor 74 together serve as a current mirror circuit. Accordingly, the second mirror-side npn transistor 74 provides a current equal to a predetermined multiple (for example, ten-fold) of the current flowing through the second current-side npn transistor 88.

The dividing section 90 allows a portion (bypass current) of the current flowing out from the second constant current source 86 to bypass the second current-side npn transistor 88 and to flow into the sink-side power source. Accordingly, the dividing section 90 can provide the collector of the second current-side npn transistor 88 with the current obtained by subtracting the bypass current from the constant current provided by the second constant current source 86. With such a configuration, the dividing section 90 can provide the adjustment constant current source 26 with a predetermined multiple (for example, ten-fold) of the current obtained by subtracting the bypass current from the constant current provided by the second constant current source 86.

Furthermore, the dividing section 90 varies the value of the bypass current according to the value of the constant current provided by the first constant current source 82. More specifically, the dividing section 90 increases the value of the bypass current as the value of the constant current provided by the first constant current source 82 increases and decreases the value of the bypass current as the value of the constant current provided by the first constant current source 82 decreases.

In the present embodiment, the dividing section 90 is an npn transistor (an npn transistor 92 for division). The npn transistor 92 for division is connected at its collector to the second constant current source 86, connected at its emitter to the sink-side power source, and connected at its base to the base of the first current-side npn transistor 84. Stated differently, the first current-side npn transistor 84 and the npn transistor 92 for division together serve as a current mirror circuit. Accordingly, the npn transistor 92 for division provides a predetermined multiple of (for example, the same current as) the current flowing through the first current-side npn transistor 84.

With such a configuration, the dividing section 90 can provide a predetermined multiple of (for example, the same current as) the current flowing through the first constant current source 82. In other words, the dividing section 90 can vary the value of the bypass current according to the value of the constant current provided by the first constant current source 82.

With the above-described configuration, the current setting section 30 can set in advance the value of the constant current (tail current) flowing through the current mode logic circuit 24. Consequently, the current setting section 30 can set in advance the voltage amplitude of the output current.

Furthermore, the current setting section 30 can vary the value of the adjustment current flowing through the adjustment constant current source 26, in accordance with the increase or decrease in the value of the tail current flowing through the in-logic constant current source 56. More specifically, the current setting section 30 can set in advance the current value in such a manner that the total of the value of the tail current flowing through the current mode logic circuit 24 and the value of the adjustment current flowing through the adjustment constant current source 26 remains constant.

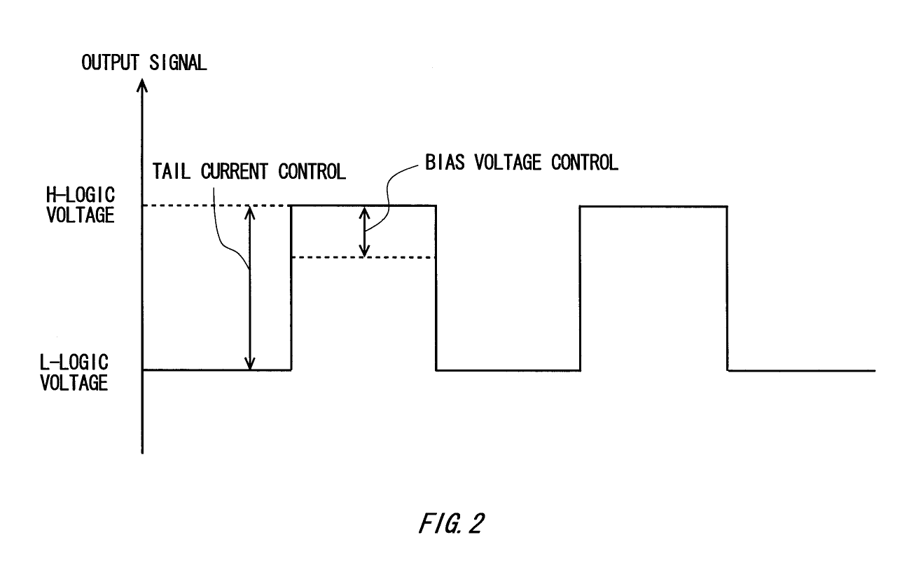

FIG. 2 shows an exemplary waveform of the output signal output from the drive circuit 10. The drive circuit 10 can output an output signal whose voltage varies between an L-logic voltage and an H-logic voltage according to the variation in the logic of the input signal.

The drive circuit 10 can vary the potential of the H-logic voltage (or the L-logic voltage) of the output signal, according to the bias voltage control from outside. In addition, the drive circuit 10 can vary the voltage amplitude of the output signal, according to external control of the value of the current (tail current) flowing through the current mode logic circuit 24.

The drive circuit 10 also varies the value of the current flowing into the adjustment constant current source 26, according to external control of the value of the current (tail current) flowing through the current mode logic circuit 24. The drive circuit 10 varies the value of the current flowing into the adjustment constant current source 26 in an inversely proportional manner to the increase or decrease in the value of the tail current. Specifically speaking, as the tail current increases by a designated value, the drive circuit 10 decreases the current flowing into the adjustment constant current source 26 by a designated value. On the other hand, as the tail current decreases by a designated value, the drive circuit 10 increases the current flowing into the adjustment constant current source 26 by a designated value.

In this manner, the drive circuit 10 can always maintain a constant total of the current flowing into the current mode logic circuit 24 and the current flowing into the adjustment constant current source 26. Furthermore, the drive circuit 10 can always keep a constant current output from the constant voltage generating section 22 to be continuously constant. In this manner, the drive circuit 10 can keep the response characteristics of the output signal and constant overall current consumption irrespective of the variation in the voltage amplitude of the output signal.

With the above-described configuration, when manufactured by using bipolar transistors, the drive circuit 10 can use npn transistors to constitute all of the internal bipolar transistors. Note that the drive circuit 10 may be manufactured by using a process utilizing CMOS transistors and that the manufacturing method may not be limited to the process utilizing bipolar transistors.

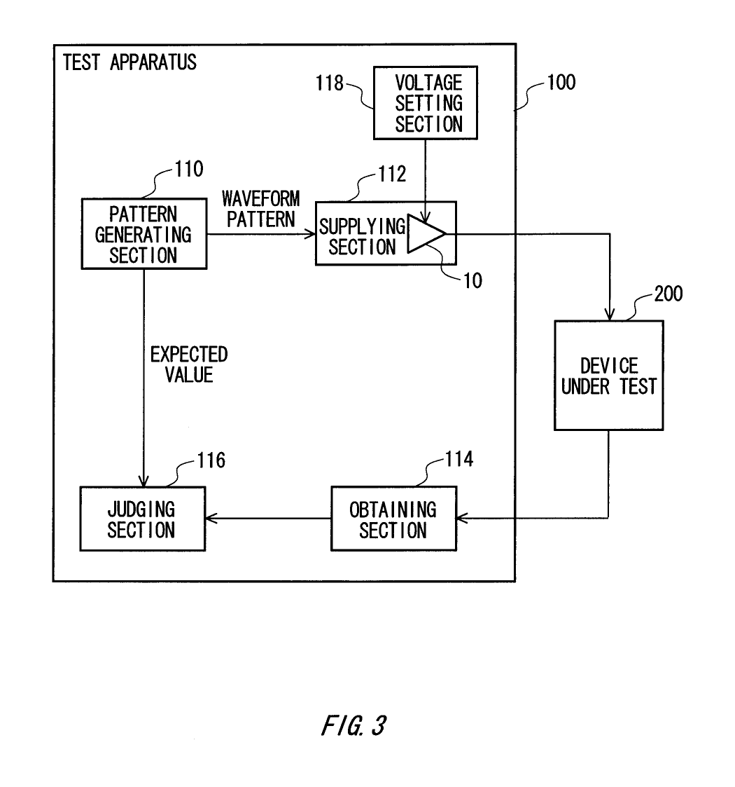

FIG. 3 illustrates the configuration of a test apparatus 100 relating to an embodiment of the present invention, together with a device under test 200. The test apparatus 100 is designed to test the device under test 200.

The test apparatus 100 includes a pattern generating section 110, a supplying section 112, an obtaining section 114, a judging section 116 and a voltage setting section 118. The pattern generating section 110 generates a waveform pattern of the signal to be supplied to the device under test 200 and an expected value to be output from the device under test 200.

The supplying section 112 supplies the device under test 200 with a test signal having a waveform determined according to the waveform pattern. The supplying section 112 includes at least one drive circuit 10 to supply the test signal to the device under test 200. The drive circuit 10 receives the waveform pattern in the form of a differential mode signal and outputs a test signal whose voltage is determined according to the logic of the differential mode signal. Here, the drive circuit 10 has the same configuration and functions as the drive circuit 10 shown in FIG. 1 and is thus not explained here.

The obtaining section 114 obtains a response signal output from the device under test 200 in response to the supplied test signal. The judging section 116 compares the value of the response signal obtained by the obtaining section 114 against the expected value to judge whether the device under test 200 is acceptable or defective.

Prior to tests, the voltage setting section 118 varies the bias voltage output from the constant voltage generating section 22 in the drive circuit 10 and the value of the constant current flowing through the current mode logic circuit 24 in order to set the logic high voltage and the logic low voltage of the test signal. With such a configuration, the test apparatus 100 can maintain the response characteristics of the drive circuit 10 and the current consumption irrespective of the variation in the potential of the H-logic voltage or L-logic voltage of the test signal and in the voltage amplitude of the test signal. Consequently, the test apparatus 100 can accurately test devices under test.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

What is claimed is:

1. A drive circuit for outputting an output signal having a voltage determined according to a logic of an input signal, the drive circuit comprising:
a constant voltage generating section that generates a constant bias voltage;
a current mode logic circuit that outputs the output signal having the voltage determined according to the logic of the input signal, an amplitude of the output signal being determined by a value of a constant current flowing through the current mode logic circuit, a potential of the output signal being determined by a value of the bias voltage;
an adjustment constant current source that allows a constant current of a set value to flow out from a bias voltage output end of the constant voltage generating section that is designed to output the bias voltage; and
a current setting section that sets in advance the value of the constant current flowing into the adjustment constant current source, according to the value of the constant current flowing through the current mode logic circuit.

2. The drive circuit as set forth in claim 1, wherein
the current setting section sets in advance the value of the constant current flowing into the adjustment constant current source in such a manner that a total of the value of the constant current flowing through the current mode logic circuit and the value of the constant current flowing into the adjustment constant current source remains constant.

3. The drive circuit as set forth in claim 1, wherein
the drive circuit receives a differential mode signal as the input signal, and
the current mode logic circuit includes:
a positive output resistance that is connected at one end thereof to a bias input end that receives the bias voltage;
a negative output resistance that is connected at one end thereof to the bias input end;
an in-logic constant current source that provides a constant current having a set value;
a positive switch that connects or disconnects between an end of the positive output resistance that is not connected to the bias input end and the in-logic constant current source, according to a logic of a positive signal of the input signal; and
a negative switch that connects or disconnects between an end of the negative output resistance that is not connected to the bias input end and the in-logic constant current source, according to a logic of a negative signal of the input signal.

4. The drive circuit as set forth in claim 3, wherein
the current mode logic circuit further includes a voltage output end that outputs a single mode signal having a voltage determined according to the input signal, the voltage output end being connected to one of (i) an end of the positive output resistance that is not connected to the bias input end and (ii) an end of the negative output resistance that is not connected to the bias input end.

5. The drive circuit as set forth in claim 1, further comprising
a voltage setting outputting section that outputs a voltage setting that is used as a reference for the bias voltage, wherein
the constant voltage generating section is a class-A power amplifier that amplifies the voltage setting output from the voltage setting outputting section and outputs the result as the bias voltage.

6. The drive circuit as set forth in claim 5, wherein
the constant voltage generating section includes:
an operational amplifier that receives the voltage setting from a non-inverted input end thereof and receives the bias voltage from an inverted input end thereof; and
an npn transistor that is connected at a collector thereof to a source-side power source, connected at an emitter thereof to the bias voltage output end of the constant voltage generating section, and connected at a base thereof to an output end of the operational amplifier.

7. The drive circuit as set forth in claim 3, wherein
the in-logic constant current source within the current mode logic circuit is a first mirror-side npn transistor that is connected at a collector thereof to the positive switch and the negative switch and connected at an emitter thereof to a sink-side power source,
the current setting section includes:
a first constant current source that provides a constant current having a set value; and
a first current-side npn transistor that is connected at a collector thereof to the first constant current source and connected at an emitter thereof to the sink-side power source, and
a base of the first current-side npn transistor is shorted to the collector of the first current-side npn transistor and connected to a base of the first mirror-side npn transistor.

8. The drive circuit as set forth in claim 7, wherein
the adjustment constant current source is a second mirror-side npn transistor that is connected at a collector thereof to the bias voltage output end of the constant voltage generating section and connected at an emitter thereof to the sink-side power source, and
the current setting section further includes:
a second constant current source that provides a constant current determined according to a reference value for the current that is expected to flow into the adjustment constant current source;
a second current-side npn transistor that is connected at a collector thereof to the second constant current source and connected at an emitter thereof to the sink-side power source, a base of the second current-side npn transistor being shorted to the collector of the second current-side npn transistor and connected to a base of the second mirror-side npn transistor; and
a dividing section that allows a portion of the current flowing out from the second constant current source to bypass the second current-side npn transistor and to flow into the sink-side power source and varies a value of the bypassing current according to the value of the constant current provided by the first constant current source.

9. The drive circuit as set forth in claim 8, wherein
the dividing section is an npn transistor for division that is connected at a collector thereof to the second constant current source, connected at an emitter thereof to the sink-side power source, and connected at a base thereof to the base of the first current-side npn transistor.

10. A test apparatus for testing a device under test, comprising:
a pattern generating section that generates a waveform pattern of a signal to be supplied to the device under test and an expected value to be output from the device under test;
a supplying section that supplies the device under test with a test signal having a waveform determined according to the waveform pattern;
an obtaining section that obtains a response signal output from the device under test in response to the supplied test signal; and
a judging section that compares a value of the response signal obtained by the obtaining section against the expected value to judge whether the device under test is acceptable, wherein
the supplying section includes at least one drive circuit as set forth in claim 1 to supply the device under test with the test signal.

11. The test apparatus as set forth in claim 10, further comprising
a voltage setting section that, prior to a test, varies the bias voltage output from the constant voltage generating section in the drive circuit and the value of the constant current flowing through the current mode logic circuit in order to set a logic-high voltage and a logic-low voltage of the test signal.
